(19) United States
(12) Patent Application Publication
(10) Pub. No.: US 2026/0122939 A1
(43) Pub. Date: Apr. 30, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takato YAMAMOTO, Kawasaki Kanagawa (JP); Yusuke KOBAYASHI, Yokohama Kanagawa (JP); Teruyuki OHASHI, Kawasaki Kanagawa (JP); Tomoko MATSUDAI, Shibuya Tokyo (JP); Kota KATO, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/221,915

(22) Filed: May 29, 2025

(30) Foreign Application Priority Data
Oct. 24, 2024 (JP) 2024-187373

(51) Int. Cl. H10D 12/00

(52) U.S. Cl. CPC H10D 12/416; H10D 12/481

(57) ABSTRACT

According to one embodiment, a semiconductor device includes first to fourth electrodes a semiconductor member, and first and second insulating members. At least a part of the semiconductor member is between the first electrode and the second electrode in a first direction from the first electrode to the second electrode. A part of the a semiconductor portion of a sixth semiconductor region of the semiconductor member is between the first electrode and a first partial region of a fifth first semiconductor region of the semiconductor member in the first direction. The first electrode is electrically connected to the fifth semiconductor region. The sixth semiconductor region is not provided between the first electrode and a fourth partial region of a fourth semiconductor region of the semiconductor member in the first direction.

### CROSS-REFERENCE TO RELATED APPLICATIONS

This application is based upon and claims the benefit of priority from Japanese Patent Application No. 2024-187373, filed on Oct. 24, 2024; the entire contents of which are incorporated herein by reference.

### FIELD

Embodiments described herein relate generally to a semiconductor device.

### BACKGROUND

For example, it is desired to improve the characteristics of semiconductor devices.

### BRIEF DESCRIPTION OF THE DRAWINGS

FIG. 1 is a schematic cross-sectional view illustrating a semiconductor device according to a first embodiment;

FIG. 2 is a schematic transparent plan view illustrating the semiconductor device according to the first embodiment;

FIG. 3 is a schematic diagram illustrating the semiconductor device according to the first embodiment;

FIG. 4 is a schematic cross-sectional view illustrating a semiconductor device according to the first embodiment;

FIG. 5 is a schematic cross-sectional view illustrating the semiconductor device according to the first embodiment;

FIG. 6 is a schematic cross-sectional view illustrating the semiconductor device according to the first embodiment;

FIG. 7 is a schematic cross-sectional view illustrating the semiconductor device according to the first embodiment;

FIG. 8 is a schematic transparent plan view illustrating the semiconductor device according to the first embodiment;

FIG. 9 is a schematic transparent plan view illustrating a semiconductor device according to the first embodiment;

FIG. 10 is a schematic transparent plane illustrating a semiconductor device according to the first embodiment;

FIG. 11 is a schematic cross-sectional view illustrating a semiconductor device according to a second embodiment;

FIG. 12 is a schematic transparent plane view illustrating the semiconductor device according to the second embodiment;

FIG. 13 is a schematic transparent plan view illustrating a semiconductor device according to the second embodiment;

FIG. 14 is a schematic transparent plan view illustrating a semiconductor device according to the second embodiment;

FIG. 15 is a schematic transparent plan view illustrating a semiconductor device according to the second embodiment;

FIG. 16 is a schematic transparent plan view illustrating a semiconductor device according to the second embodiment;

FIG. 17 is a schematic transparent plan view illustrating a semiconductor device according to the second embodiment;

FIG. 18 is a schematic transparent plan view illustrating a semiconductor device according to the second embodiment; and

FIG. 19 is a schematic cross-sectional view illustrating a semiconductor device according to a third embodiment.

### DETAILED DESCRIPTION

According to one embodiment, a semiconductor device includes a first electrode, a second electrode, a third electrode, a fourth electrode, a semiconductor member, a first insulating member, and a second insulating member. At least a part of the semiconductor member is between the first electrode and the second electrode in a first direction from the first electrode to the second electrode. The semiconductor member includes a first semiconductor region of a first conductivity type, a second semiconductor region of a second conductivity type, a third semiconductor region of the first conductivity type, a fourth semiconductor region of the first conductivity type, a fifth semiconductor region of the second conductivity type, and a sixth semiconductor region of the first conductivity type. The second electrode is electrically connected to the third semiconductor region. At least a part of the second semiconductor region is between the first semiconductor region and the third semiconductor region. At least a part of the first insulating member is between the third electrode and the first semiconductor region, between the third electrode and the second semiconductor region, and between the third electrode and the third semiconductor region. The fifth semiconductor region includes a first partial region, a second partial region, a third partial region, and a fourth partial region. The fourth semiconductor region is between the second partial region and the fourth partial region in a second direction crossing the first direction. The sixth semiconductor region includes a first semiconductor portion. The first semiconductor portion is between the third partial region and the fourth semiconductor region in the second direction. The second partial region is between the first semiconductor portion and the fourth semiconductor region. A part of the first semiconductor portion is between the first electrode and the first partial region in the first direction. Another part of the first semiconductor portion is between the fourth electrode and the first partial region in the first direction. The fourth partial region is provided between the first electrode and the first semiconductor region in the first direction. At least a part of the second insulating member is provided between the fourth electrode and the first semiconductor portion, between the fourth electrode and the second partial region, and between the fourth electrode and the fourth semiconductor region. The first electrode is electrically connected to the fifth semiconductor region. The sixth semiconductor region is not provided between the first electrode and the fourth partial region in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

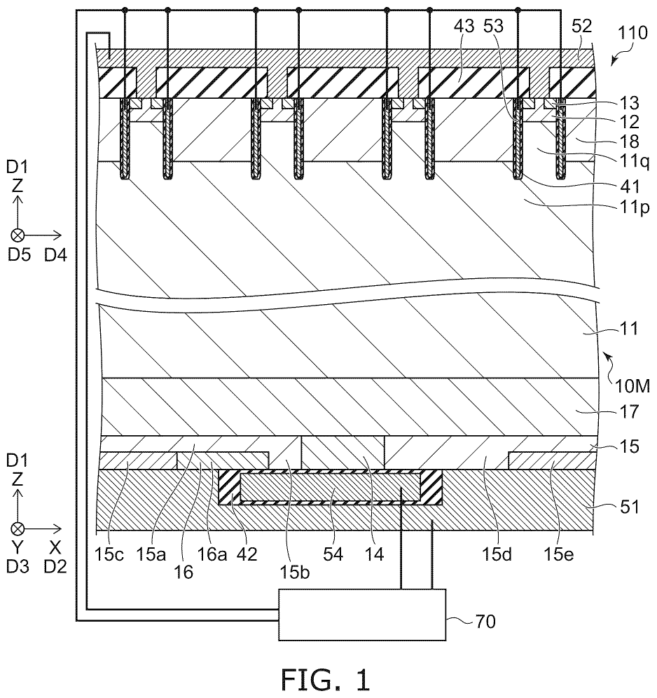

FIG. 1 is a schematic cross-sectional view illustrating a semiconductor device according to a first embodiment.

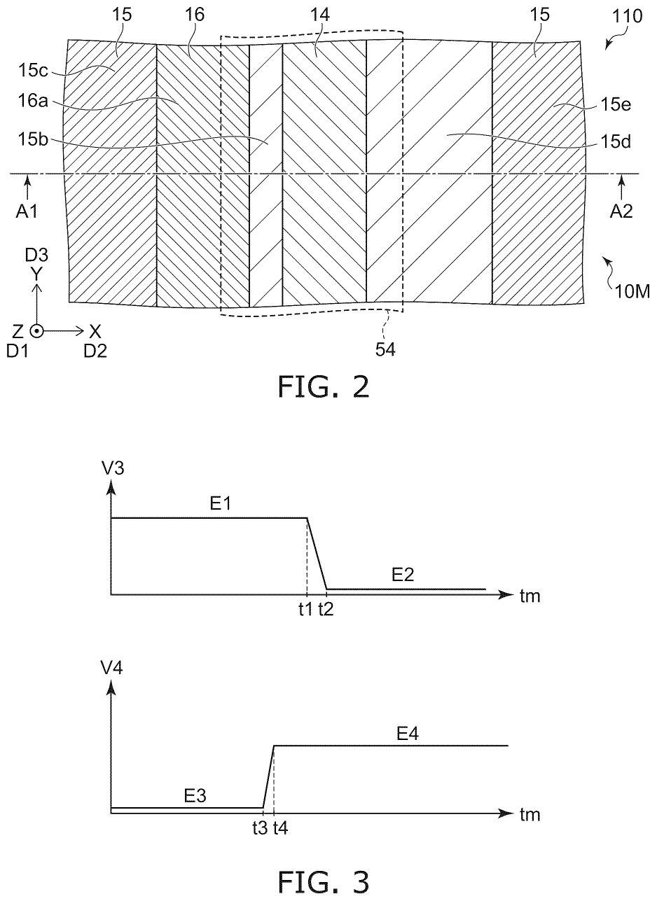

FIG. 2 is a schematic transparent plan view illustrating the semiconductor device according to the first embodiment.

FIG. 1 corresponds to the cross-sectional view taken along the line A1-A2 in FIG. 2.

As shown in FIG. 1, a semiconductor device 110 according to the embodiment includes a first electrode 51, a second electrode 52, a third electrode 53, a fourth electrode 54, a semiconductor member 10M, a first insulating member 41, and a second insulating member 42.

At least a part of the semiconductor member 10M is located between the first electrode 51 and the second electrode 52 in a first direction D1 from the first electrode 51 to the second electrode 52.

The first direction D1 is defined as a Z-axis direction. One direction perpendicular to the Z-axis direction is defined as a X-axis direction. A direction perpendicular to the Z-axis direction and the X-axis direction is defined as a Y-axis direction.

The semiconductor member 10M includes a first semiconductor region 11 of a first conductivity type, a second semiconductor region 12 of a second conductivity type, a third semiconductor region 13 of the first conductivity type, a fourth semiconductor region 14 of the first conductivity type, a fifth semiconductor region 15 of the second conductivity type, and a sixth semiconductor region 16 of the first conductivity type. The first conductivity type is one of n-type and p-type. The second conductivity type is the other of n-type and p-type. In the following, the first conductivity type is n-type, and the second conductivity type is p-type.

The second electrode 52 is electrically connected to the third semiconductor region 13. At least a part of the second semiconductor region 12 is located between the first semiconductor region 11 and the third semiconductor region 13. At least a part of the first insulating member 41 is located between the third electrode 53 and a part of the first semiconductor region 11, between the third electrode 53 and the second semiconductor region 12, and between the third electrode 53 and the third semiconductor region 13. At least a part of the third electrode 53 faces a part of the first semiconductor region 11, the second semiconductor region 12, and the third semiconductor region 13.

The fifth semiconductor region 15 includes a first partial region 15a, a second partial region 15b, a third partial region 15c, and a fourth partial region 15d. The fifth semiconductor region 15 may further include other partial regions (for example, a fifth partial region 15e, etc.). The boundaries between these partial regions may be clear or unclear.

The fourth semiconductor region 14 is located between the second partial region 15b and the fourth partial region 15d in a second direction D2 crossing the first direction D1.

The sixth semiconductor region 16 includes a first semiconductor portion 16a. The first semiconductor portion 16a is located between the third partial region 15c and the fourth semiconductor region 14 in the second direction D2. The second partial region 15b is located between the first semiconductor portion 16a and the fourth semiconductor region 14 in the second direction D2.

A part of the first semiconductor portion 16a is located between the first electrode 51 and the first partial region 15a in the first direction D1. Another part of the first semiconductor portion 16a is located between the fourth electrode 54 and the first partial region 15a in the first direction D1.

The fourth partial region 15d is located between the first electrode 51 and the first semiconductor region 11 in the first direction D1. In this example, a part of the fourth partial region 15d is located between the fifth partial region 15e and the first semiconductor region 11 in the first direction D1.

At least a part of the second insulating member 42 is located between the fourth electrode 54 and the first semiconductor portion 16a, between the fourth electrode 54 and the second partial region 15b, and between the fourth electrode 54 and the fourth semiconductor region 14. The first electrode 51 is electrically connected to the fifth semiconductor region 15. For example, the first electrode 51 is electrically connected to the third partial region 15c, the fourth partial region 15d, and the fifth partial region 15e. The first electrode 51 may contact the third partial region 15c, the fourth partial region 15d, and the fifth partial region 15e.

As shown in FIG. 1, the sixth semiconductor region 16 is not provided between the first electrode 51 and the fourth partial region 15d in the first direction D1. As shown in FIG. 1, the semiconductor member 10M is asymmetric with respect to an axis including the fourth electrode 54 and aligned with the first direction D1. For example, the sixth semiconductor region 16 is not provided between the fourth semiconductor region 14 and the fifth partial region 15e.

The current flowing between the first electrode 51 and the second electrode 52 can be controlled by the potential of the third electrode 53. The first electrode 51 functions as a collector electrode. The second electrode 52 functions as an emitter electrode. The third electrode 53 functions as a gate electrode. The semiconductor device 110 is, for example, an IGBT (Insulated Gate Bipolar Transistor).

The semiconductor device 110 includes the fourth electrode 54 described above. A part of the fourth electrode 54 faces the sixth semiconductor region 16 of the first conductivity type, a part of the fifth semiconductor region 15 of the second conductivity type, and the fourth semiconductor region 14 of the first conductivity type. By controlling the potential of the fourth electrode 54, for example, the charge (e.g., holes) injected from the first electrode 51 can be controlled. For example, the charge (e.g., holes) injected from the fifth semiconductor region 15 toward the seventh semiconductor region 17 described later can be controlled.

In the left part of FIG. 1, a current path including the first semiconductor portion 16a, the second partial region 15b, and the fourth semiconductor region 14 can be controlled by the potential of the fourth electrode 54. For example, when the potential of the fourth electrode 54 exceeds a threshold value, a current path is formed in the part of the second partial region 15b facing the fourth electrode 54. By controlling the potential of the fourth electrode 54, the current path is opened and closed. For example, in the open state of the current path, electrons can move from the fourth semiconductor region 14 toward the first electrode 51 via the second partial region 15b and the first semiconductor portion 16a. For example, electrons are discharged toward the first electrode 51.

On the other hand, in the right part of FIG. 1, such a current path is not provided. In the right part of FIG. 1, the potential of the fourth electrode 54 controls the injection of holes from the first electrode 51 to the first semiconductor region 11 via the fourth partial region 15d. This is considered to be because the potential of the region including the fourth semiconductor region 14 and the fourth partial region 15d is controlled by the potential of the fourth electrode 54. This is considered to be a phenomenon associated with the discharge of charges in the left part of FIG. 1.

In the embodiment, electrons are discharged by switching the current path including the first semiconductor portion 16a, the second partial region 15b, and the fourth semiconductor region 14. Meanwhile, in the region including the fourth partial region 15d, hole injection is controlled by controlling the potential. Carriers can be effectively controlled by a plurality of different mechanisms. In the semiconductor device 110, hole injection may be controlled in the region including the first partial region 15a.

In the embodiment, efficient discharge of electrons and suppression of hole injection are effectively implemented. For example, conduction loss is effectively suppressed. According to the embodiment, a semiconductor device capable of improving characteristics is provided.

As shown in FIG. 1, the semiconductor device 110 may be provided with a controller 70. The controller 70 may be included in the semiconductor device 110. The controller 70 may be provided separately from the semiconductor device 110. The controller 70 is electrically connected to the first electrode 51, the second electrode 52, the third electrode 53, and the fourth electrode 54. An example of the operation of the semiconductor device 110 will be described below.

FIG. 3 is a schematic diagram illustrating the semiconductor device according to the first embodiment.

In FIG. 3, the horizontal axis is time tm. In FIG. 3, the potential of the third electrode 53 (third electrode potential V3) and the potential of the fourth electrode 54 (fourth electrode potential V4) are illustrated. The controller 70 is configured to perform a first operation. This corresponds to an off operation in the semiconductor device 110.

As shown in FIG. 3, in the first operation, the controller 70 is configured to set the third electrode potential V3 of the third electrode 53 to a first potential E1 based on the second electrode potential of the second electrode 52 at a first time t1. In the first operation, the controller 70 is configured to set the third electrode potential V3 to a second potential E2 based on the second electrode potential at a second time t2. The second time t2 is after the first time t1. The first potential E1 is higher than the second potential E2. In the first operation, the controller 70 is configured to set the fourth electrode potential V4 of the fourth electrode 54 to a third potential E3 based on the first electrode potential of the first electrode 51 at a third time t3. In the first operation, the controller 70 is configured to set the fourth electrode potential V4 to a fourth potential E4 based on the first electrode potential at a fourth time t4. The fourth time t4 is after the third time t3. The third potential E3 is lower than the fourth potential E4. The fourth time t4 is before the second time t2 or is the same as the second time t2.

Such an operation may be applied to the third electrode 53 and the fourth electrode 54. By appropriately controlling the potential of the fourth electrode 54, for example, electrons are effectively discharged. By applying an asymmetric configuration, for example, appropriate opening and closing of the current path and suppression of hole injection in the region including the fourth partial region 15d are performed. For example, losses can be effectively reduced. A semiconductor device with improved characteristics can be provided. In the embodiment, for example, a current path is formed on one side of the fourth electrode 54 in the second direction D2. For example, the current density can be increased. For example, the constraints on the position of the fourth electrode 54 are relaxed, and the fourth electrode 54 can be stably obtained with high productivity.

As shown in FIG. 2, at least a part of the fourth electrode 54 may extend along a third direction D3. The third direction D3 crosses a plane including the first direction D1 and the second direction D2. The third direction D3 may be, for example, the Y-axis direction.

The fourth semiconductor region 14 may extend along the third direction D3. The first semiconductor portion 16a may extend along the third direction D3.

As shown in FIG. 1, the semiconductor member 10M may further include a seventh semiconductor region 17 of the first conductivity type. A part of the seventh semiconductor region 17 is located between the fourth semiconductor region 14 and the first semiconductor region 11 in the first direction D1. Another part of the seventh semiconductor region 17 is located between the fifth semiconductor region 15 and the first semiconductor region 11 in the first direction D1. An impurity concentration of the first conductivity type in the seventh semiconductor region 17 is higher than an impurity concentration of the first conductivity type in the first semiconductor region 11.

As shown in FIG. 1, in this example, the direction from the third electrode 53 to the second semiconductor region 12 is along the fourth direction D4 that crosses with the first direction D1. The direction from the third electrode 53 to the third semiconductor region 13 is along the fourth direction D4.

The fourth direction D4 may be along the second direction D2. The fourth direction D4 may cross the second direction D2. An angle between the fourth direction D4 and the second direction D2 is arbitrary.

As shown in FIG. 1, in this example, a direction from a part 10p of the first semiconductor region 11 to the third electrode 53 is along the first direction D1. A direction from the third electrode 53 to another part 10q of the first semiconductor region 11 is along the fourth direction D4. In this example, the third electrode 53 is a trench gate. The third electrode 53 may extend along a fifth direction D5. The fifth direction D5 crosses a plane including the first direction D1 and the fourth direction D4.

In this example, the semiconductor member 10M includes an eighth semiconductor region 18 of the second conductivity type. In the fourth direction D4, the third electrode 53 may be provided between the eighth semiconductor region 18 and the second semiconductor region 12.

In the embodiment, a direction from the third semiconductor region 13 to the third electrode 53 may be along the first direction D1.

A plurality of the third electrodes 53 may be provided. The plurality of third electrodes 53 are arranged along the fourth direction D4.

In the embodiment, a plurality of the fourth electrodes 54 may be provided. The plurality of fourth electrodes 54 extend in the fifth direction D5. The plurality of fourth electrodes 54 may be arranged along the fourth direction D4. A set including the first partial region 15a, the fourth semiconductor region 14, and the fourth partial region 15d is provided corresponding to one fourth electrode 54. The plurality of sets may be arranged along the second direction D2.

A pitch (second pitch) of the plurality of fourth electrodes 54 in the second direction D2 may be longer than a pitch (first pitch) of the plurality of third electrodes 53 in the fourth direction D4.

For example, in a first reference example, the sixth semiconductor region 16 is provided between the fourth electrode 54 and the fourth partial region 15d. In the first reference example, two sixth semiconductor regions 16 are provided, and two current paths are opened and closed corresponding to the potential of one fourth electrode 54. In the first reference example, the semiconductor member 10M is symmetrical with respect to an axis that includes the fourth electrode 54 and extends along the first direction D1.

On the other hand, in the embodiment, one sixth semiconductor region 16 is provided corresponding to one of the plurality of fourth electrodes 54. One current path is opened and closed corresponding to the potential of one fourth electrode 54. When the pitch of the plurality of fourth electrodes 54 in the embodiment is the same as the pitch in the first reference example, the density of the sixth semiconductor region 16 corresponding to the pitch in the embodiment is ½ of the density in the first reference example. In the embodiment, charge control by the potential of the fourth electrode 54 can be performed without compromising the area of the fifth semiconductor region 15, compared to the first reference example.

In the first reference example, when the area of the sixth semiconductor region 16 is large and the area of the fifth semiconductor region 15 is small, for example, the area of the region contributing to charge injection when the current path is closed becomes small. This, for example, increases the conduction loss. In the first reference example, for example, the change in the potential of the fourth semiconductor region 14 occurring in response to the change in the potential of the fourth electrode 54 is likely to be excessively reduced. This tends to reduce the time margin for switching. For example, the influence is large when the switching timing of the third electrode 53 and the fourth electrode 54 is shifted from the appropriate timing, making it difficult to achieve stable operation.

In contrast, in the embodiment, the density of the sixth semiconductor region 16 is half that of the first reference example, and the area of the fifth semiconductor region 15 is large. In the embodiment, for example, the area of the region that contributes to charge injection when the current path is closed is large. This, for example, can reduce conduction loss. For example, the power per volume can be increased. For example, the time margin can be increased. For example, the impact when the switching timing of the third electrode 53 and the fourth electrode 54 is shifted from the appropriate timing is small. Stable operation is easily obtained. When the current path is opened by the potential of the fourth electrode 54, charge control equal to or greater than that of the first reference example is possible. This, for example, can reduce the combined loss of conduction loss and turn-off loss.

In the embodiment, an impurity concentration of the first conductivity type in the sixth semiconductor region 16 (sixth impurity concentration) may be higher than an impurity concentration of the first conductivity type in the fourth semiconductor region 14 (fourth impurity concentration). The sixth impurity concentration is, for example, not less than 1×10¹⁴ cm⁻³ and not more than 1×10²¹ cm⁻³. The fourth impurity concentration is, for example, not less than 1×10¹¹ cm⁻³ and not more than 1×10¹⁵ cm⁻³.

An impurity concentration of the second conductivity type in the third partial region 15c (third partial region impurity concentration) may be higher than an impurity concentration of the second conductivity type in the second partial region 15b (second partial region impurity concentration). The third partial region impurity concentration may be, for example, not less than 1×10¹³ cm⁻³ and not more than 1×10²¹ cm⁻³. The second partial region impurity concentration may be, for example, not less than 1×10¹³ cm⁻³ and not more than 1×10¹⁹ cm⁻³. The third partial region impurity concentration may be higher than a second conductivity type impurity concentration (first partial region impurity concentration) in the first partial region 15a. The first partial region impurity concentration may be, for example, not less than 1×10¹³ cm⁻³ and not more than 1×10¹⁹ cm⁻³.

An impurity concentration of the second conductivity type in the fifth partial region 15e (fifth partial region impurity concentration) may be higher than an impurity concentration of the second conductivity type in the fourth partial region 15d (fourth partial region impurity concentration). The fifth partial region impurity concentration may be, for example, not less than 1×10¹³ cm⁻³ and not more than 1×10²¹ cm⁻³. The fourth partial region impurity concentration may be, for example, not less than 1×10¹³ cm⁻³ and not more than 1×10¹⁹ cm⁻³.

An impurity concentration of the first conductivity type in the third semiconductor region 13 (third impurity concentration) is higher than an impurity concentration of the first conductivity type in the first semiconductor region 11 (first impurity concentration). The third impurity concentration may be, for example, not less than 1×10¹⁴ cm⁻³ and not more than 1×10²¹ cm⁻³. The first impurity concentration may be, for example, not less than 1×10¹¹ cm⁻³ and not more than 1×10¹⁵ cm⁻³.

An impurity concentration of the first conductivity type in the seventh semiconductor region 17 may be, for example, not less than 1×10¹³ cm⁻³ and not more than 1×10¹⁹ cm⁻³. An impurity concentration of the second conductivity type in the eighth semiconductor region 18 may be, for example, not less than 1×10¹¹ cm⁻³ and not more than 1×10¹⁸ cm⁻³.

As shown in FIG. 1, the semiconductor device 110 may further include a third insulating member 43. At least a part of the third insulating member 43 is located between the third electrode 53 and the second electrode 52.

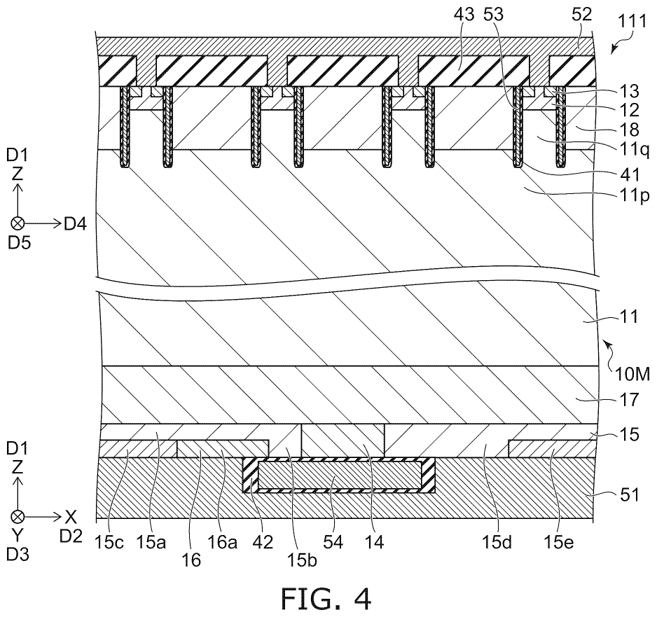

FIGS. 4 to 7 are schematic cross-sectional views illustrating a semiconductor device according to the first embodiment.

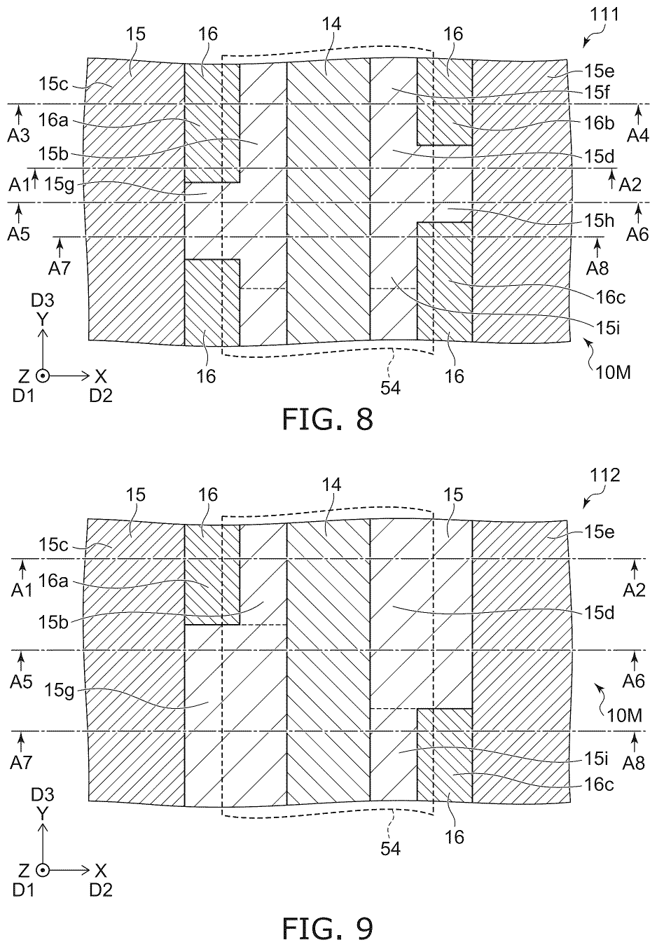

FIG. 8 is a schematic transparent plan view illustrating the semiconductor device according to the first embodiment.

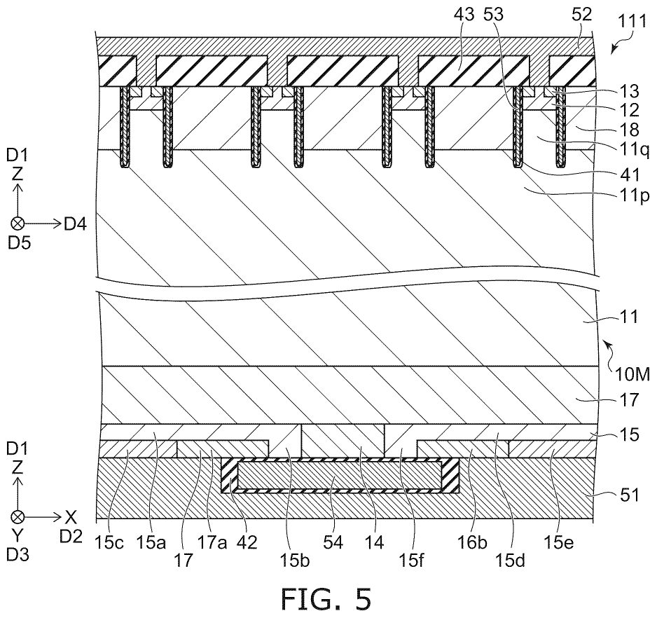

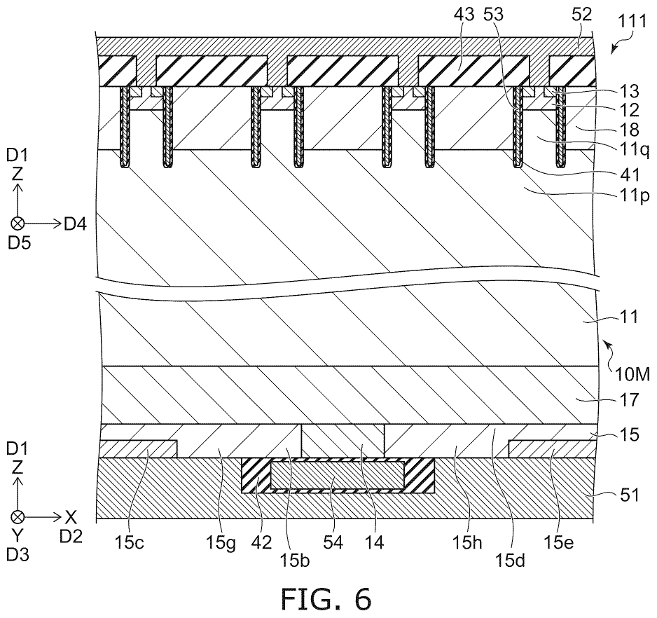

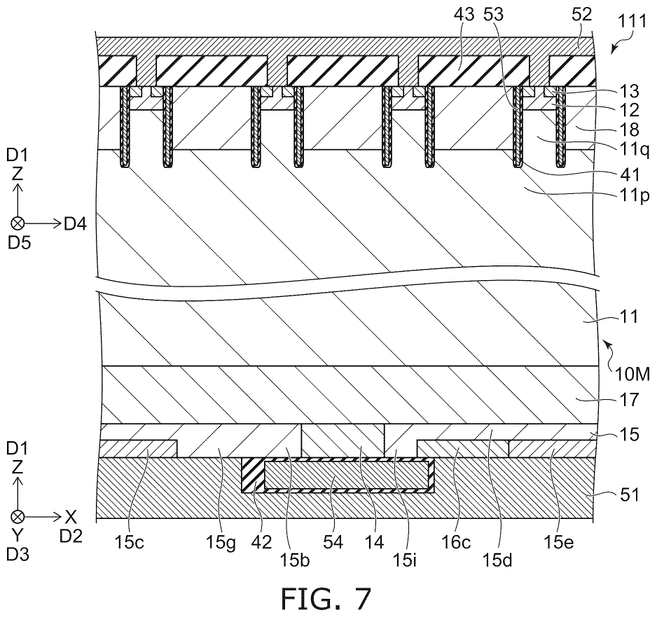

FIG. 4 corresponds to the cross-sectional view taken along the line A1-A2 in FIG. 8. FIG. 5 corresponds to the cross-sectional view taken along the line A3-A4 in FIG. 8. FIG. 6 corresponds to a cross-sectional view taken along the line A5-A6 in FIG. 8. FIG. 7 corresponds to a cross-sectional view taken along the line A7-A8 in FIG. 8.

As shown in FIG. 8, in a semiconductor device 111 according to the embodiment, the sixth semiconductor region 16 further includes a third semiconductor portion 16c. The configuration of the semiconductor device 112 except for this may be the same as the configuration of the semiconductor device 110.

As shown in FIGS. 5 and 8, the sixth semiconductor region 16 may further include the second semiconductor portion 16b. The fourth semiconductor region 14 is located between the second partial region 15b and the second semiconductor portion 16b in the second direction D2. The second semiconductor portion 16b is located between the first electrode 51 and a part of the fourth partial region 15d in the first direction D1.

In this example, the fifth semiconductor region 15 further includes a fifth partial region 15e and a sixth partial region 15f. The sixth partial region 15f is located between the fourth semiconductor region 14 and the second semiconductor portion 16b in the second direction D2. The second semiconductor portion 16b is located between the sixth partial region 15f and the fifth partial region 15e in the second direction D2. A part of the fourth electrode 54 faces the sixth partial region 15f and the second semiconductor portion 16b in the first direction D1. The first electrode 51 is electrically connected to the fifth partial region 15e.

As shown in FIG. 5, a part of the semiconductor member 10M may be symmetrical with respect to an axis that includes the fourth electrode 54 and extends along the first direction D1. As shown in FIG. 4, another part of the semiconductor member 10M may be asymmetric with respect to an axis that includes the fourth electrode 54 and extends along the first direction D1. With this configuration as well, conduction loss is effectively suppressed. The characteristics can be improved.

As shown in FIGS. 6 and 8, the fifth semiconductor region 15 may further include a seventh partial region 15g. As shown in FIG. 8, a third direction D3 from the seventh partial region 15g to the first semiconductor portion 16a crosses a plane including the first direction D1 and the second direction D2.

As shown in FIGS. 6 and 8, the fifth semiconductor region 15 may further include an eighth partial region 15h. As shown in FIG. 8, a direction from the eighth partial region 15h to the second semiconductor portion 16b is along the third direction D3. As shown in FIG. 6, another part of the semiconductor member 10M may be symmetrical with respect to an axis including the fourth electrode 54 and along the first direction D1.

As shown in FIGS. 7 and 8, the sixth semiconductor region 16 may further include the third semiconductor portion 16c. The eighth partial region 15h is located between the third semiconductor portion 16c and the second semiconductor portion 16b in the third direction D3.

As shown in FIGS. 7 and 8, the fifth semiconductor region 15 may further include a ninth partial region 15i. The ninth partial region 15i is located between the fourth semiconductor region 14 and the third semiconductor portion 16c in the second direction D2.

As shown in FIG. 7, a part of the fourth electrode 54 faces the ninth partial region 15i and the third semiconductor portion 16c in the first direction D1. As shown in FIG. 7, another part of the semiconductor member 10M may be asymmetric with respect to an axis that includes the fourth electrode 54 and extends along the first direction D1.

FIG. 9 is a schematic transparent plan view illustrating a semiconductor device according to the first embodiment.

As shown in FIG. 9, in a semiconductor device 112 according to the embodiment, the sixth semiconductor region 16 further includes the third semiconductor portion 16c. The configuration of the semiconductor device 112 except for this may be the same as the configuration of the semiconductor device 110.

In the semiconductor device 112, the fifth semiconductor region 15 further includes the ninth partial region 15i. The ninth partial region 15i is located between the fourth semiconductor region 14 and the third semiconductor portion 16c in the second direction D2. A position of the third semiconductor portion 16c in the third direction D3 (third semiconductor portion position) is different from a position of the first semiconductor portion 16a in the third direction D3 (first semiconductor portion position). As already explained, the third direction D3 crosses a plane including the first direction D1 and the second direction D2.

As in the semiconductor device 112, in the two parts of the semiconductor member 10M, asymmetric configuration with respect to an axis including the fourth electrode 54 and being along the first direction D1 can be applied.

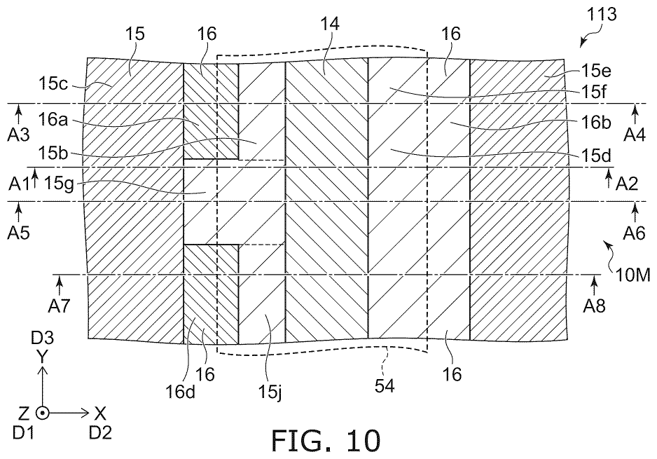

FIG. 10 is a schematic transparent plane illustrating a semiconductor device according to the first embodiment.

As shown in FIG. 10, in a semiconductor device 113 according to the embodiment, the sixth semiconductor region 16 further includes a fourth semiconductor portion 16d. The configuration of the semiconductor device 113 except for this may be the same as the configuration of the semiconductor device 110.

The fifth semiconductor region 15 may further include the seventh partial region 15g and a tenth partial region 15j. The tenth partial region 15j is located between the fourth semiconductor portion 16d and the fourth semiconductor region 14 in the second direction D2. The seventh partial region 15g is located between the fourth semiconductor portion 16d and the first semiconductor portion 16a in the third direction D3. As already explained, the third direction D3 crosses a plane including the first direction D1 and the second direction D2.

As shown in FIGS. 2, 8, 9 and 10, in the semiconductor device 110, the semiconductor device 111, the semiconductor device 112 and the semiconductor device 113, the fourth electrode 54 may overlap the second partial region 15b and the fourth partial region 15d in the first direction D1.

### Second Embodiment

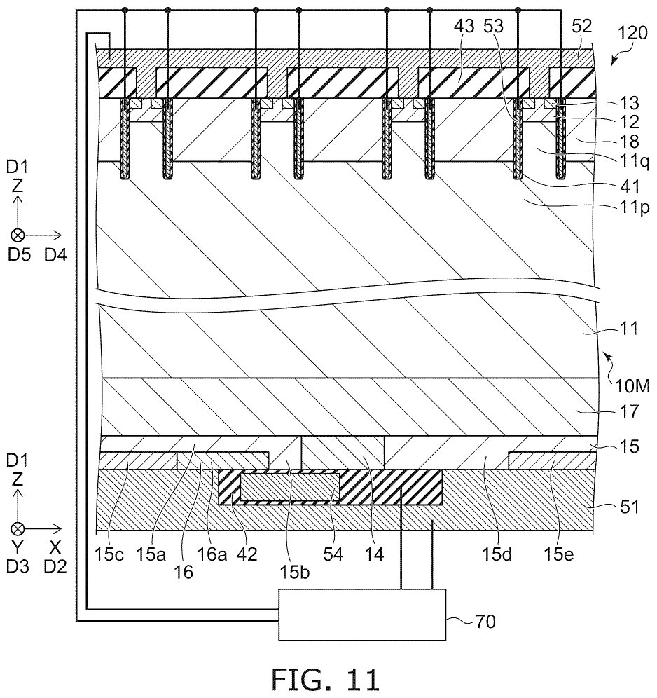

FIG. 11 is a schematic cross-sectional view illustrating a semiconductor device according to the second embodiment.

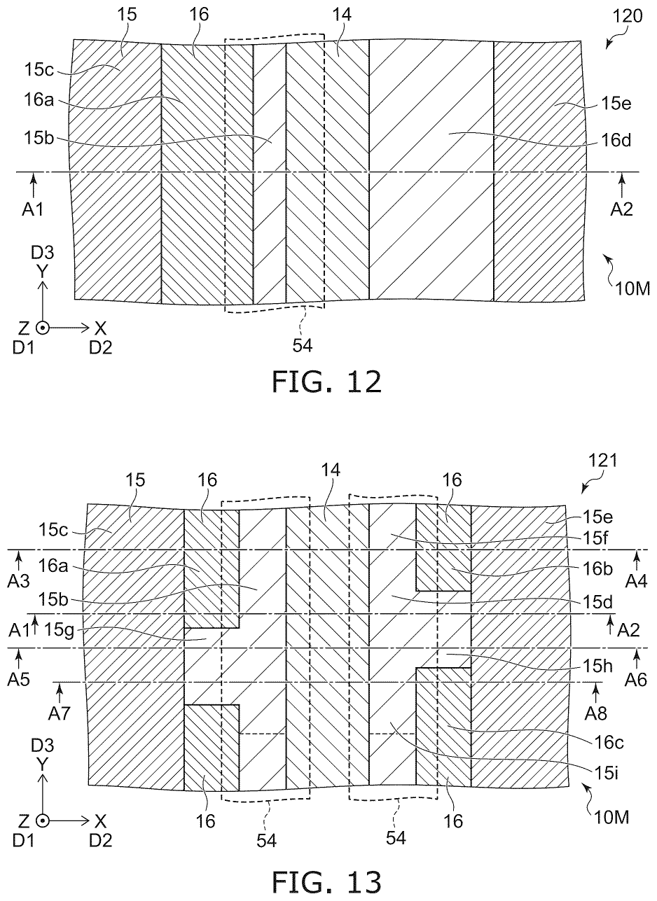

FIG. 12 is a schematic transparent plane view illustrating the semiconductor device according to the second embodiment.

FIG. 11 is a cross-sectional view taken along the line A1-A2 in FIG. 12.

As shown in FIGS. 11 and 12, in a semiconductor device 120 according to the embodiment, the configuration of the fourth electrode 54 differs from that in the semiconductor device 110. The configuration of the semiconductor device 120 except for this may be the same as the configuration of the semiconductor device 110.

As shown in FIGS. 11 and 12, in the semiconductor device 120, the fourth electrode 54 overlaps the first semiconductor portion 16a, the second partial region 15b, and the fourth semiconductor region 14 in the first direction D1. The fourth electrode 54 does not overlap the fourth partial region 15d in the first direction D1. In such a semiconductor device 120, the opening and closing of the current path including the first semiconductor portion 16a, the second partial region 15b, and the fourth semiconductor region 14 is controlled by controlling the potential of the fourth electrode 54. For example, the potential of the fourth semiconductor region 14 can be controlled by controlling the potential of the fourth electrode 54. By appropriately controlling the potential of the fourth semiconductor region 14, for example, the injection of holes from the fourth partial region 15d into the first semiconductor region 11 is suppressed. The conduction loss is effectively suppressed. Characteristics can be improved. For example, the controllability of opening and closing the current path of the second partial region 15b can be improved.

FIG. 13 is a schematic transparent plan view illustrating a semiconductor device according to the second embodiment.

As shown in FIG. 13, in a semiconductor device 121 according to the embodiment, a plurality of the fourth electrodes 54 are provided. The configuration of the semiconductor device 121 except for this may be the same as the configuration of the semiconductor device 111.

In the semiconductor device 121, one of the plurality of fourth electrodes 54 overlaps the first semiconductor portion 16a and the fourth semiconductor region 14 in the first direction D1. Another one of the plurality of fourth electrodes 54 overlaps the second semiconductor portion 16b and the fourth semiconductor region 14 in the first direction D1.

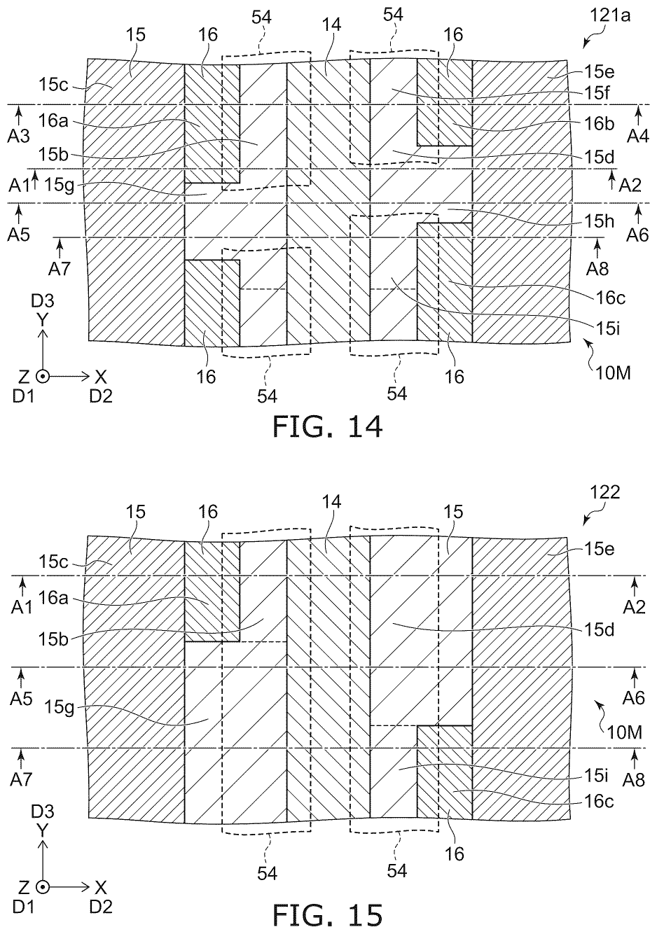

FIG. 14 is a schematic transparent plan view illustrating a semiconductor device according to the second embodiment.

As shown in FIG. 14, in a semiconductor device 121a according to the embodiment, the plurality of fourth electrodes 54 are provided. he configuration of the semiconductor device 121a except for this may be the same as the configuration of the semiconductor device 111.

In the semiconductor device 121a, one of the plurality of fourth electrodes 54 overlaps the first semiconductor portion 16a and the fourth semiconductor region 14 in the first direction D1. Another one of the plurality of fourth electrodes 54 overlaps the third semiconductor portion 16c and the fourth semiconductor region 14 in the first direction D1. Yet another one of the plurality of fourth electrodes 54 may overlap the second semiconductor portion 16b and the fourth semiconductor region 14 in the first direction D1.

FIG. 15 is a schematic transparent plan view illustrating a semiconductor device according to the second embodiment.

As shown in FIG. 15, in a semiconductor device 122 according to the embodiment, the plurality of fourth electrodes 54 are provided. The configuration of the semiconductor device 122 except for this may be the same as the configuration of the semiconductor device 112.

In the semiconductor device 122, one of the plurality of fourth electrodes 54 overlaps the first semiconductor portion 16a and the fourth semiconductor region 14 in the first direction D1. Another one of the plurality of fourth electrodes 54 overlaps the third semiconductor portion 16c and the fourth semiconductor region 14 in the first direction D1. A direction from one of the plurality of fourth electrodes 54 to the other one of the plurality of fourth electrodes 54 is along the second direction D2.

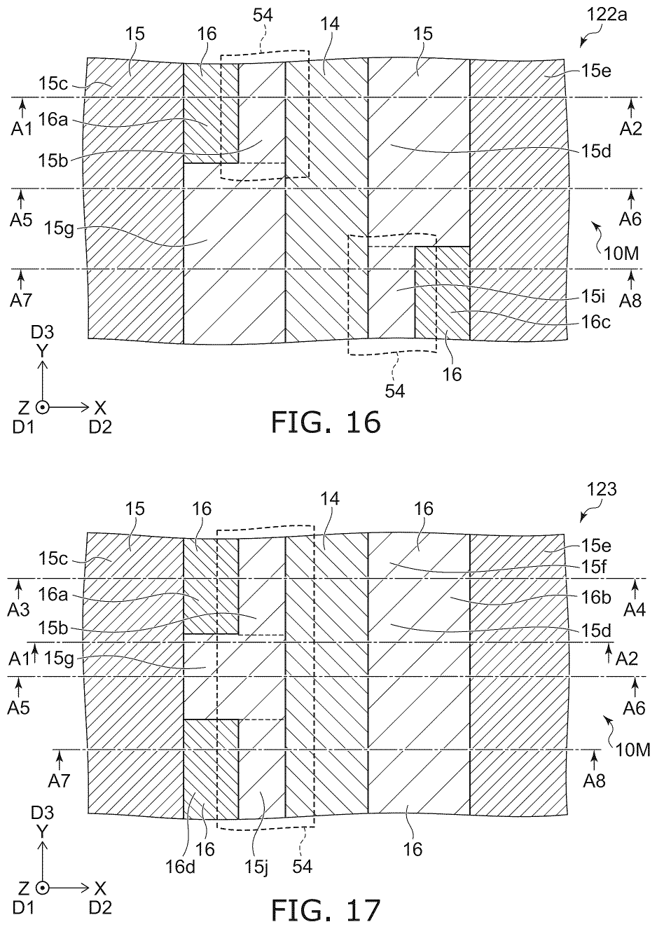

FIG. 16 is a schematic transparent plan view illustrating a semiconductor device according to the second embodiment.

As shown in FIG. 16, in a semiconductor device 122a according to the embodiment, the plurality of fourth electrodes 54 are provided. The configuration of the semiconductor device 122a except for this may be the same as the configuration of the semiconductor device 112.

In the semiconductor device 122a, one of the plurality of fourth electrodes 54 overlaps the first semiconductor portion 16a and the fourth semiconductor region 14 in the first direction D1. Another one of the plurality of fourth electrodes 54 overlaps the third semiconductor portion 16c and the fourth semiconductor region 14 in the first direction D1. The one of the plurality of fourth electrodes 54 does not overlap the other one of the plurality of fourth electrodes 54 in the second direction D2.

FIG. 17 is a schematic transparent plan view illustrating a semiconductor device according to the second embodiment.

As shown in FIG. 17, in a semiconductor device 123 according to the embodiment, the configuration of the fourth electrode 54 differs from that in the semiconductor device 113. The configuration of the semiconductor device 123 except for this may be the same as the configuration of the semiconductor device 113.

In the semiconductor device 123, the fourth electrode 54 overlaps the first semiconductor portion 16a, the fourth semiconductor portion 16d, and the fourth semiconductor region 14. The fourth electrode 54 does not overlap the fourth partial region 15d.

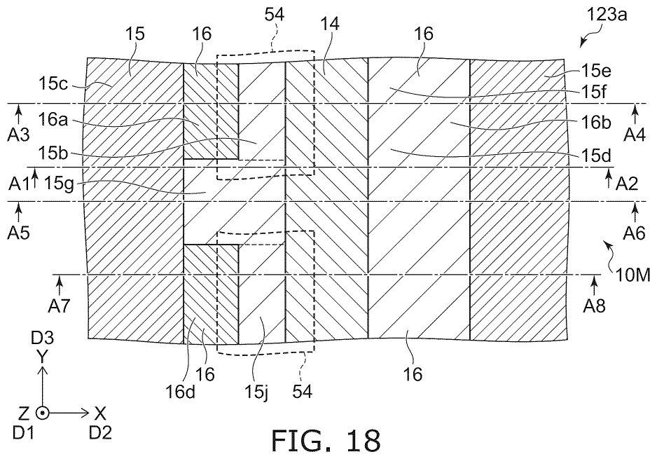

FIG. 18 is a schematic transparent plan view illustrating a semiconductor device according to the second embodiment.

As shown in FIG. 18, in a semiconductor device 123a according to the embodiment, the configuration of the fourth electrode 54 differs from that in the semiconductor device 113. The configuration of the semiconductor device 123 except for this may be the same as the configuration of the semiconductor device 113.

In the semiconductor device 123a, one of the plurality of fourth electrodes 54 overlaps the first semiconductor portion 16a and the fourth semiconductor region 14. Another one of the plurality of fourth electrodes 54 overlaps the fourth semiconductor portion 16d and the fourth semiconductor region 14. Each of the plurality of fourth electrodes 54 does not overlap the fourth partial region 15d.

In the semiconductor device 121, the semiconductor device 121a, the semiconductor device 122, the semiconductor device 122a, the semiconductor device 123, and the semiconductor device 123a, for example, the conduction loss is effectively suppressed. The characteristics can be improved.

### Third Embodiment

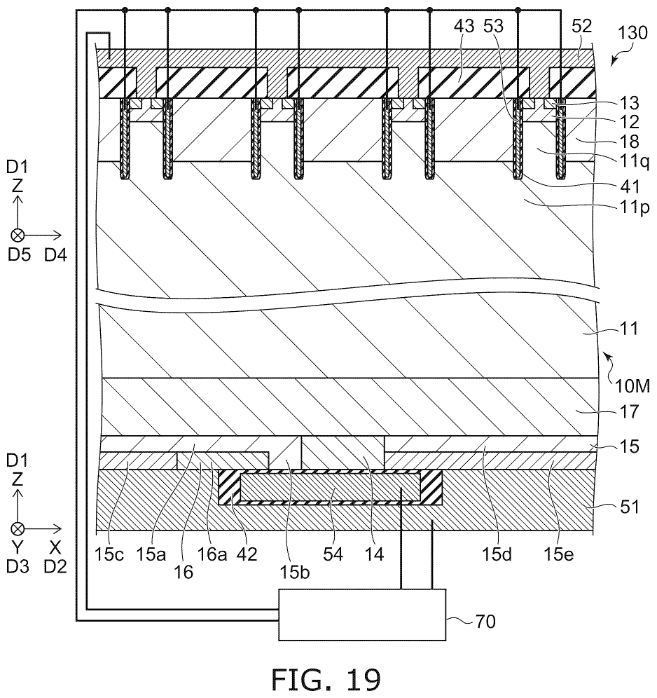

FIG. 19 is a schematic cross-sectional view illustrating a semiconductor device according to the third embodiment.

As shown in FIG. 19, in a semiconductor device 130 according to the embodiment, the configuration of the fourth partial region 15d differs from that in the semiconductor device according to the first or second embodiment. The configuration of the semiconductor device 130 except for this may be the same as the configuration of the semiconductor device according to the first or second embodiment (e.g., the semiconductor device 110).

In the semiconductor device 130, the fifth partial region 15e is located between the first electrode 51 and the fourth partial region 15d. The fourth partial region 15d is located between the fifth partial region 15e and the first semiconductor region 11. In the semiconductor device 130, for example, the conduction loss is also effectively suppressed. The characteristics can be improved. The configuration described with respect to the semiconductor device 130 may be applied to, for example, the first embodiment, the second embodiment, and their modifications.

In the embodiment, at least one of the first electrode 51 or the second electrode 52 may include a metal. The metal may include at least one selected from the group consisting of Al, Ti, Ni, Au, Ag, and Cu. At least one of the third electrode 53 or the fourth electrode 54 may include polysilicon. The semiconductor member 10M may include silicon. The semiconductor member 10M may include a compound semiconductor. The compound semiconductor may include at least one selected from the group consisting of SiC, GaN, GaO, and GaAs.

In the embodiment, information on the shape of the semiconductor region is obtained, for example, from an electron microscope image. Information on the composition and element concentration is obtained, for example, from EDX (Energy Dispersive X-ray Spectroscopy) or SIMS (Secondary Ion Mass Spectrometry). Information on the composition may be obtained, for example, from reciprocal space mapping.

The embodiment may include the following Technical proposals:

### Technical Proposal 1

A semiconductor device, comprising:
a first electrode;
a second electrode;
a third electrode;
a fourth electrode;
a semiconductor member;
a first insulating member; and
a second insulating member,
at least a part of the semiconductor member being between the first electrode and the second electrode in a first direction from the first electrode to the second electrode,
the semiconductor member including:
   a first semiconductor region of a first conductivity type;
   a second semiconductor region of a second conductivity type;
   a third semiconductor region of the first conductivity type;
   a fourth semiconductor region of the first conductivity type;
   a fifth semiconductor region of the second conductivity type; and
   a sixth semiconductor region of the first conductivity type,
the second electrode being electrically connected to the third semiconductor region,
at least a part of the second semiconductor region being between the first semiconductor region and the third semiconductor region,
at least a part of the first insulating member being between the third electrode and the first semiconductor region, between the third electrode and the second semiconductor region, and between the third electrode and the third semiconductor region,
the fifth semiconductor region including a first partial region, a second partial region, a third partial region, and a fourth partial region,
the fourth semiconductor region being between the second partial region and the fourth partial region in a second direction crossing the first direction,
the sixth semiconductor region including a first semiconductor portion,
the first semiconductor portion being between the third partial region and the fourth semiconductor region in the second direction,
the second partial region being between the first semiconductor portion and the fourth semiconductor region,
a part of the first semiconductor portion being between the first electrode and the first partial region in the first direction,
another part of the first semiconductor portion being between the fourth electrode and the first partial region in the first direction,
the fourth partial region being provided between the first electrode and the first semiconductor region in the first direction,
at least a part of the second insulating member being provided between the fourth electrode and the first semiconductor portion, between the fourth electrode and the second partial region, and between the fourth electrode and the fourth semiconductor region,
the first electrode being electrically connected to the fifth semiconductor region, and
the sixth semiconductor region being not provided between the first electrode and the fourth partial region in the first direction.

### Technical Proposal 2

The semiconductor device according to Technical proposal 1, wherein
the sixth semiconductor region further includes a second semiconductor portion,
the fourth semiconductor region is located between the second partial region and the second semiconductor portion in the second direction, and
the second semiconductor portion is located between the first electrode and a part of the fourth partial region in the first direction.

### Technical Proposal 3

The semiconductor device according to Technical proposal 2, wherein
the fifth semiconductor region further includes a fifth partial region and a sixth partial region,
the sixth partial region is located between the fourth semiconductor region and the second semiconductor portion in the second direction, and
the second semiconductor portion is located between the sixth partial region and the fifth partial region in the second direction.

### Technical Proposal 4

The semiconductor device according to Technical proposal 2, wherein
the fifth semiconductor region further includes a seventh partial region, and
a third direction from the seventh partial region to the first semiconductor portion crosses a plane including the first direction and the second direction.

### Technical Proposal 5

The semiconductor device according to Technical proposal 4, wherein
the fifth semiconductor region further includes an eighth partial region, and
a direction from the eighth partial region to the second semiconductor portion is along the third direction.

### Technical Proposal 6

The semiconductor device according to Technical proposal 5, wherein
the sixth semiconductor region further includes a third semiconductor portion,
the eighth partial region is located between the third semiconductor portion and the second semiconductor portion in the third direction.

### Technical Proposal 7

The semiconductor device according to Technical proposal 6, wherein
the fifth semiconductor region further includes a ninth partial region, and
the ninth partial region is located between the fourth semiconductor region and the third semiconductor region in the second direction.

### Technical Proposal 8

The semiconductor device according to any one of Technical proposals 2-7, comprising:
a plurality of the fourth electrodes,
one of the plurality of the fourth electrodes overlapping the first semiconductor portion and the fourth semiconductor region in the first direction, and
another one of the plurality of the fourth electrodes overlapping the second semiconductor portion and the fourth semiconductor region in the first direction.

### Technical Proposal 9

The semiconductor device according to Technical proposal 6 or 7, comprising:
a plurality of the fourth electrodes,
one of the plurality of the fourth electrodes overlapping the first semiconductor portion and the fourth semiconductor region in the first direction, and
another one of the plurality of the fourth electrodes overlapping the third semiconductor portion and the fourth semiconductor region in the first direction.

### Technical Proposal 10

The semiconductor device according to any one of Technical proposals 1-9, wherein
the fourth electrode overlaps the fourth partial region in the first direction.

### Technical Proposal 11

The semiconductor device according to any one of Technical proposals 1-9, wherein
the fourth electrode does not overlap the fourth partial region in the first direction.

### Technical Proposal 12

The semiconductor device according to Technical proposal 1, wherein
the sixth semiconductor region further includes a third semiconductor portion,
the fifth semiconductor region further includes a ninth partial region,
the ninth partial region is located between the fourth semiconductor region and the third semiconductor portion in the second direction,
a third semiconductor portion position in a third direction of the third semiconductor portion is different from a first semiconductor portion position in the third direction of the first semiconductor portion, and
the third direction crosses a plane including the first direction and the second direction.

### Technical Proposal 13

The semiconductor device according to Technical proposal 1, wherein
the sixth semiconductor region further includes a fourth semiconductor portion,
the fifth semiconductor region further includes a seventh partial region and a tenth partial region,
the tenth partial region is located between the fourth semiconductor portion and the fourth semiconductor region in the second direction, and
the seventh partial region is located between the fourth semiconductor portion and the first semiconductor portion in a third direction crossing a plane including the first direction and the second direction.

### Technical Proposal 14

The semiconductor device according to any one of Technical proposals 1-13, wherein
a sixth impurity concentration of the first conductivity type in the sixth semiconductor region is higher than a fourth impurity concentration of the first conductivity type in the fourth semiconductor region.

### Technical Proposal 15

The semiconductor device according to any one of Technical proposals 1-13, wherein

a third partial region impurity concentration of the second conductivity type in the third partial region is higher than a second partial region impurity concentration of the second partial region of the second conductivity type in the second partial region.

### Technical Proposal 16

The semiconductor device described in Technical proposal 3, wherein
a fifth partial region impurity concentration of the second conductivity type in the fifth partial region is higher than a second partial region impurity concentration of the second conductivity type in the fourth partial region.

### Technical Proposal 17

The semiconductor device according to any one of Technical proposals 1-16, wherein
a third impurity concentration of the first conductivity type in the third semiconductor region is higher than a first impurity concentration of the first conductivity type in the first semiconductor region.

### Technical Proposal 18

The semiconductor device according to any one of Technical proposals 1-17, wherein
a direction from the third electrode to the second semiconductor region is along a fourth direction that crosses the first direction, and
a direction from the third electrode to the third semiconductor region is along the fourth direction.

### Technical Proposal 19

The semiconductor device according to any one of Technical proposals 1-18, further comprising:
a third insulating member,
at least a part of the third insulating member being located between the third electrode and the second electrode.

### Technical Proposal 20

The semiconductor device according to any one of Technical proposals 1-9, further comprising:
a controller configured to perform a first operation,
in the first operation, the controller being configured to set a third electrode potential of the third electrode to a first potential based on a second electrode potential of the second electrode at a first time,
in the first operation, the controller being configured to set the third electrode potential to a second potential based on the second electrode potential at a second time after the first time,
the first potential being higher than the second potential,
in the first operation, the controller being configured to set a fourth electrode potential of the fourth electrode to a third potential based on the first electrode potential of the first electrode at a third time,
in the first operation, the controller being configured to set the fourth electrode potential of the fourth electrode to a fourth potential based on the first electrode potential of the first electrode at a fourth time after the third time,
the third potential being lower than the fourth potential,
the fourth time being earlier than the second time or the same as the second time.

According to the embodiment, a semiconductor device is provided that can improve characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode;
a fourth electrode;
a semiconductor member;
a first insulating member; and
a second insulating member,
at least a part of the semiconductor member being between the first electrode and the second electrode in a first direction from the first electrode to the second electrode,
the semiconductor member including:
a first semiconductor region of a first conductivity type;
a second semiconductor region of a second conductivity type;
a third semiconductor region of the first conductivity type;
a fourth semiconductor region of the first conductivity type;
a fifth semiconductor region of the second conductivity type; and
a sixth semiconductor region of the first conductivity type,
the second electrode being electrically connected to the third semiconductor region,
at least a part of the second semiconductor region being between the first semiconductor region and the third semiconductor region,
at least a part of the first insulating member being between the third electrode and the first semiconductor region, between the third electrode and the second semiconductor region, and between the third electrode and the third semiconductor region,
the fifth semiconductor region including a first partial region, a second partial region, a third partial region, and a fourth partial region,
the fourth semiconductor region being between the second partial region and the fourth partial region in a second direction crossing the first direction,
the sixth semiconductor region including a first semiconductor portion,
the first semiconductor portion being between the third partial region and the fourth semiconductor region in the second direction,
the second partial region being between the first semiconductor portion and the fourth semiconductor region,
a part of the first semiconductor portion being between the first electrode and the first partial region in the first direction,
another part of the first semiconductor portion being between the fourth electrode and the first partial region in the first direction,
the fourth partial region being provided between the first electrode and the first semiconductor region in the first direction,
at least a part of the second insulating member being provided between the fourth electrode and the first semiconductor portion, between the fourth electrode and the second partial region, and between the fourth electrode and the fourth semiconductor region,
the first electrode being electrically connected to the fifth semiconductor region, and
the sixth semiconductor region being not provided between the first electrode and the fourth partial region in the first direction.

2. The semiconductor device according to claim 1, wherein
the sixth semiconductor region further includes a second semiconductor portion,
the fourth semiconductor region is located between the second partial region and the second semiconductor portion in the second direction, and
the second semiconductor portion is located between the first electrode and a part of the fourth partial region in the first direction.

3. The semiconductor device according to claim 2, wherein
the fifth semiconductor region further includes a fifth partial region and a sixth partial region,
the sixth partial region is located between the fourth semiconductor region and the second semiconductor portion in the second direction, and
the second semiconductor portion is located between the sixth partial region and the fifth partial region in the second direction.

4. The semiconductor device according to claim 2, wherein
the fifth semiconductor region further includes a seventh partial region, and
a third direction from the seventh partial region to the first semiconductor portion crosses a plane including the first direction and the second direction.

5. The semiconductor device according to claim 4, wherein
the fifth semiconductor region further includes an eighth partial region, and
a direction from the eighth partial region to the second semiconductor portion is along the third direction.

6. The semiconductor device according to claim 5, wherein
the sixth semiconductor region further includes a third semiconductor portion,
the eighth partial region is located between the third semiconductor portion and the second semiconductor portion in the third direction.

7. The semiconductor device according to claim 6, wherein
the fifth semiconductor region further includes a ninth partial region, and
the ninth partial region is located between the fourth semiconductor region and the third semiconductor region in the second direction.

8. The semiconductor device according to claim 2, comprising:
a plurality of the fourth electrodes,
one of the plurality of the fourth electrodes overlapping the first semiconductor portion and the fourth semiconductor region in the first direction, and
another one of the plurality of the fourth electrodes overlapping the second semiconductor portion and the fourth semiconductor region in the first direction.

9. The semiconductor device according to claim 6, comprising:
a plurality of the fourth electrodes,
one of the plurality of the fourth electrodes overlapping the first semiconductor portion and the fourth semiconductor region in the first direction, and
another one of the plurality of the fourth electrodes overlapping the third semiconductor portion and the fourth semiconductor region in the first direction.

10. The semiconductor device according to claim 1, wherein
the fourth electrode overlaps the fourth partial region in the first direction.

11. The semiconductor device according to claim 1, wherein
the fourth electrode does not overlap the fourth partial region in the first direction.

12. The semiconductor device according to claim 1, wherein
the sixth semiconductor region further includes a third semiconductor portion,
the fifth semiconductor region further includes a ninth partial region,
the ninth partial region is located between the fourth semiconductor region and the third semiconductor portion in the second direction,
a third semiconductor portion position in a third direction of the third semiconductor portion is different from a first semiconductor portion position in the third direction of the first semiconductor portion, and
the third direction crosses a plane including the first direction and the second direction.

13. The semiconductor device according to claim 1, wherein
the sixth semiconductor region further includes a fourth semiconductor portion,
the fifth semiconductor region further includes a seventh partial region and a tenth partial region,
the tenth partial region is located between the fourth semiconductor portion and the fourth semiconductor region in the second direction, and
the seventh partial region is located between the fourth semiconductor portion and the first semiconductor portion in a third direction crossing a plane including the first direction and the second direction.

14. The semiconductor device according to claim 1, wherein
a sixth impurity concentration of the first conductivity type in the sixth semiconductor region is higher than a fourth impurity concentration of the first conductivity type in the fourth semiconductor region.

15. The semiconductor device according to claim 1, wherein
a third partial region impurity concentration of the second conductivity type in the third partial region is higher than a second partial region impurity concentration of the second partial region of the second conductivity type in the second partial region.

16. The semiconductor device according to claim 3, wherein
a fifth partial region impurity concentration of the second conductivity type in the fifth partial region is higher than a second partial region impurity concentration of the second conductivity type in the fourth partial region.

17. The semiconductor device according to claim 1, wherein
a third impurity concentration of the first conductivity type in the third semiconductor region is higher than a first impurity concentration of the first conductivity type in the first semiconductor region.

18. The semiconductor device according to claim 1, wherein
a direction from the third electrode to the second semiconductor region is along a fourth direction that crosses the first direction, and
a direction from the third electrode to the third semiconductor region is along the fourth direction.

19. The semiconductor device according to claim 1, further comprising:
a third insulating member,
at least a part of the third insulating member being located between the third electrode and the second electrode.

20. The semiconductor device according to claim 1, further comprising:
a controller configured to perform a first operation,
in the first operation, the controller being configured to set a third electrode potential of the third electrode to a first potential based on a second electrode potential of the second electrode at a first time,
in the first operation, the controller being configured to set the third electrode potential to a second potential based on the second electrode potential at a second time after the first time,
the first potential being higher than the second potential,
in the first operation, the controller being configured to set a fourth electrode potential of the fourth electrode to a third potential based on the first electrode potential of the first electrode at a third time,
in the first operation, the controller being configured to set the fourth electrode potential of the fourth electrode to a fourth potential based on the first electrode potential of the first electrode at a fourth time after the third time,
the third potential being lower than the fourth potential,
the fourth time being earlier than the second time or the same as the second time.
